(19) United States
(12) Patent Application Publication
(10) Pub. No.: US 2025/0006665 A1
(43) Pub. Date: Jan. 2, 2025

(54) METHODS AND APPARATUS FOR STACKS OF GLASS LAYERS INCLUDING DEEP TRENCH CAPACITORS

(71) Applicant: Intel Corporation, Santa Clara, CA (US)

(72) Inventors: Gang Duan, Chandler, AZ (US); Minglu Liu, Chandler, AZ (US); Srinivas Venkata Ramanuja Pietambaram, Chandler, AZ (US)

(73) Assignee: Intel Corporation, Santa Clara, CA (US)

(21) Appl. No.: 18/883,825

(22) Filed: Sep. 12, 2024

(51) Int. Cl. H01L 23/64; H01L 23/00; H01L 23/15; H01L 23/31; H01L 23/498; H01L 23/535; H01L 25/11; H01L 25/18; H01L 29/66

(52) U.S. Cl. CPC H01L 23/642; H01L 23/15; H01L 23/3128; H01L 23/49816; H01L 23/49822; H01L 23/49827; H01L 23/535; H01L 24/16; H01L 24/17; H01L 24/32; H01L 24/73; H01L 25/117; H01L 25/18; H01L 29/66181; H01L 2224/16225; H01L 2224/1703; H01L 2224/32157; H01L 2224/32165; H01L 2224/73204; H01L 2924/1205

(57) ABSTRACT

Systems, apparatus, articles of manufacture, and methods for stacks of glass layers including deep trench capacitors are disclosed. An example substrate for an integrated circuit package disclosed herein includes a first glass layer, a second glass layer coupled to the first glass layer, and a deep trench capacitor embedded in the first core.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery. One option being pursued is the implementation of package substrates with glass cores. Generally, glass core implementations offer several advantages compared to implementations with conventional epoxy cores, including a higher plated through-hole (PTH) density, lower signal losses, and lower total thickness variation.

### BRIEF DESCRIPTION OF THE DRAWINGS

FIG. 1 illustrates an example integrated circuit (IC) package constructed in accordance with teachings disclosed herein.

FIG. 2A illustrates an example first substrate core that may be used to implement the example substrate core of FIG. 1.

FIG. 2B illustrates an example second substrate core that may be used to implement the example substrate core of FIG. 1.

FIGS. 3-13 illustrate different intermediate stages in an example fabrication process to manufacture the example substrate cores of FIGS. 2A and 2B.

FIG. 14 illustrates an intermediate stage in an example fabrication process to manufacture the example first substrate core of FIG. 2A.

FIG. 15 illustrates an intermediate stage in an example fabrication process to manufacture the example second substrate core of FIG. 2B.

FIG. 16 is a flowchart representative of example methods that may be performed to fabricate any one of the substrate cores of FIGS. 2A-2B.

FIG. 17 is a top view of a wafer including dies that may be included in an IC package constructed in accordance with teachings disclosed herein.

FIG. 18 is a cross-sectional side view of an IC device that may be included in an IC package constructed in accordance with teachings disclosed herein.

FIG. 19 is a cross-sectional side view of an IC device assembly that may include an IC package constructed in accordance with teachings disclosed herein.

FIG. 20 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

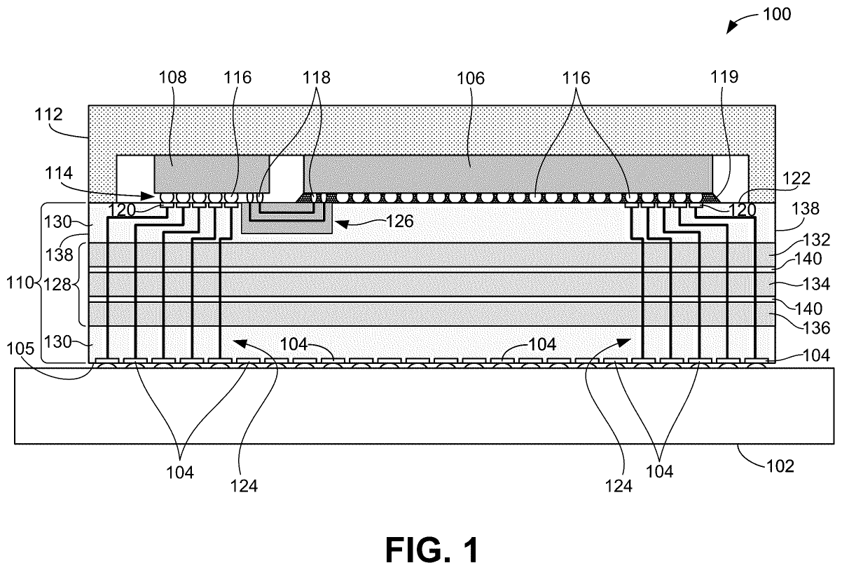

FIG. 1 illustrates an example integrated circuit (IC) package 100 constructed in accordance with teachings disclosed herein. In the illustrated example, the IC package 100 is electrically coupled to a circuit board 102 via an array of lands 104 (also referred to herein as contact pads) on a bottom surface 105 (e.g., a bottom external surface, a mounting surface, etc.) of the package. In some examples, the IC package 100 may include balls, pins, and/or pads, in addition to or instead of the lands 104, to enable the electrical coupling of the IC package 100 to the circuit board 102. In this example, the IC package 100 includes two semiconductor dies 106, 108 (e.g., silicon dies, etc.) (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the package substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the package substrate 110 (e.g., the interconnects 114) are sometimes referred to as first level interconnects. By contrast, the electrical connections between the IC package 100 and the circuit board 102 (e.g., the lands 104, etc.) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the lands 104 on the bottom surface 105 (e.g., the bottom external surface, etc.) of the package substrate 110 (e.g., a surface opposite the inner surface 122) via internal interconnects 124 within the package substrate 110. As a result, there is a continuous electrical signal path between the core bumps 116 of the dies 106, 108 and the lands 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 (e.g. silicon-based interconnect die, etc.) embedded in the package substrate 110. As represented in FIG. 1, core bumps 116 are typically larger than bridge bumps 118. In some examples, the interconnect bridge 126 and the associated bridge bumps 118 are omitted.

In some examples, an underfill material 119 is disposed between the dies 106, 108 and the package substrate 110 around and/or between the first level interconnects 114 (e.g., around and/or between the core bumps 116 and/or the bridge bumps 118). In the illustrated example, only the first die 106 is associated with the underfill material 119. However, in other examples, both dies 106, 108 are associated with the underfill material 119. In other examples, the underfill material 119 is omitted. In some examples, the mold compound 112 is used as an underfill material that surrounds the first level interconnects 114.

In some examples, the IC package 100 includes additional passive components, such as surface-mount resistors, capacitors, and/or inductors disposed on the bottom surface 105 of the package substrate 110 and/or the inner surface 122 (e.g., the top surface, etc.) of the package substrate 110.

In FIG. 1, the package substrate 110 of the example IC package 100 includes a substrate core 128 (e.g., a main core, an overall core) between two separate build-up regions 130 (e.g., build-up layers, buffer layers). As shown in the illustrated example, the substrate core 128 includes multiple distinct glass cores (e.g., multiple glass layers, multiple glass core layers, etc.), namely an example top glass core 132 (e.g., a first glass core, etc.), an example middle glass core 134 (e.g., a second glass core, etc.), and an example bottom glass core 136 (e.g., a third glass core, etc.). In the illustrated example of FIG. 1, the glass cores 132, 134, 136 (e.g., sub-cores, glass substrates, glass layers, glass sheets, etc.) are vertically stacked on top of one another.

In some examples, the glass cores 132, 134, 136 include at least one of: aluminosilicate, borosilicate, alumino-borosilicate, silica, and/or fused silica. In some examples, the glass cores 132, 134, 136 include one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass cores 132, 134, 136 include silicon and oxygen. In some examples, the glass cores 132, 134, 136 include silicon, oxygen, and/or one or more of aluminum, boron, magnesium, calcium, barium, tin, sodium, potassium, strontium, phosphorus, zirconium, lithium, titanium, and/or zinc. In some examples, the glass cores 132, 134, 136 include at least 23 percent silicon by weight and at least 26 percent oxygen by weight. In some examples, the glass cores 132, 134, 136 are individual layers of glass including silicon, oxygen, and aluminum. In some examples, the glass cores 132, 134, 136 include at least 23 percent silicon by weight, at least 26 percent oxygen by weight, and at least 5 percent aluminum by weight.

In some examples, the glass cores 132, 134, 136 are amorphous solid glass layers. In some examples, the glass cores 132, 134, 136 are layers of glass that do not include an organic adhesive or an organic material. In some examples, the glass cores 132, 134, 136 are solid layers of glass having a same rectangular shape in plan view. In other examples, some or all of the glass cores 132, 134, 136 have different shapes. In some examples, the glass cores 132, 134, 136, as glass substrates, include at least one glass layer and do not include epoxy and do not include glass fibers (e.g., do not include an epoxy-based prepreg layer with glass cloth). In some examples, the glass cores 132, 134, 136 correspond to single pieces of glass that extend the full height/thickness of each corresponding core.

In some examples, the glass cores 132, 134, 136 have a rectangular shape that is substantially coextensive, in plan view, with the layers above and/or below the core. In some examples, the glass cores 132, 134, 136 have a thickness in a range of about 25 micrometers (μm) to about 400 μm (with the overall thickness of the substrate core 128 ranging from about 50 μm to about 1.4 millimeters (mm)). In some examples, the glass cores 132, 134, 136 can have dimensions of about 10 mm on a side to about 250 mm on a side (e.g., 10 mm by 10 mm to 250 mm by 250 mm). In some examples, the glass cores 132, 134, 136 correspond to rectangular prism volumes with sections (e.g., vias) removed and filled with other materials (e.g., metal).

The build-up regions 130 are represented in FIG. 1 as masses/blocks with the internal interconnects 124 extending in straight lines through the build-up regions 130 (and the glass cores 132, 134, 136). However, FIG. 1 has been simplified for the sake of clarity and purposes of explanation. In practice, the interconnects are not necessarily straight. More particularly, in some examples, the build-up regions 130 are defined by alternating layers of dielectric material and layers of conductive material (e.g., a metal such as copper, etc.). The conductive (metal) layers serve as the basis for the internal interconnects 124 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers. Further, the electrical routing or traces on either side of the substrate core 128 may be electrically coupled by through-glass vias (TGVs) (e.g., copper-plated vias) extending through the glass cores 132, 134, 136.

Among other things, glass cores are advantageous over epoxy-based cores because glass is stiffer and, therefore, provides greater mechanical support or strength for the package substrate. Thus, the substrate core 128 and, more particularly, the individual ones of the glass cores 132, 134, 136 are example means for strengthening the package substrate. In addition to mechanical benefits, glass cores also provide other advantages including a higher plated through-hole (PTH) density, lower signal losses, and a lower total thickness variation. However, glass cores also present challenges due to the fragile (e.g., brittle) nature of glass and the possibility of defects that can develop into cracks that propagate through the glass.

A common type of failure of known glass cores is referred to as a seware failure. Seware failures result in the separation of a glass core along a crack that propagates from an edge of the glass core along its length and width between the main outer surfaces (e.g., upper and lower surfaces, front and back surfaces) of the glass core. That is, seware failures are characterized by a glass core being split into two separate sheets of glass along a line extending generally parallel to the main plane of the glass core.

Factors that contribute to seware failures include defects on the edges of glass cores resulting from singulation and the internal stress induced by a mismatch in coefficient of thermal expansion (CTE) between the glass core and the material in the build-up regions during thermal cycles of the package substrate 110. More particularly, package substrates, such as the package substrate 110 of FIG. 1, are often fabricated on a large panel that is subsequently singulated or cut into individual units with a saw. Thus, in the illustrated example of FIG. 1, the package substrate 110, including the substrate core 128 (and the associated glass cores 132, 134, 136) and the build-up regions 130, include opposing edges 138 that are created by the cut of a saw. Such sawing can result in defects developing on the edges of glass cores (e.g., the edges 138 of the glass cores 132, 134, 136 in FIG. 1) that can give rise to cracks that propagate laterally across the middle of the glass core to split the glass core in two. The development and propagation of cracks in this manner are exacerbated by stress induced by fluctuations in temperature and the difference in CTE of the build-up regions relative to the CTE of the glass core. Generally, the material in the build-up regions 130 has a higher CTE than glass. As a result, the material in the build-up regions 130 expands and contracts more than a glass core in response to thermal fluctuations, thereby causing internal stress within the glass core that can promote crack propagation.

Examples disclosed herein reduce (minimize) concerns for seware failures by implementing the substrate core 128 of the substrate with multiple distinct (e.g., disaggregated, etc.) glass cores (e.g., the glass cores 132, 134, 136, etc.) stacked on top of one another as shown in FIG. 1. More particularly, in examples disclosed herein, the glass cores 132, 134, 136 are implemented by different materials (or different compositions of the same materials) associated with different CTEs. In some examples, the glass cores that are closer to the build-up regions 130 are fabricated with a CTE that is closer to the CTE of the build-up regions 130 than the CTE of the glass cores farther away from the build-up regions 130 (e.g., closer to the middle of the stack of glass cores). In this manner, the substrate core 128 is defined by a gradation of CTEs or incremental changes in CTE (between each of the glass core 132, 134, 136) that provide a transition between the different layers in the package substrate 110 to reduce stress at any given location. Thus, in some examples, the middle glass core 134 has a lower CTE than the top glass core 132 and a lower CTE than the bottom glass core 136. In some examples, the CTE of the top glass core 132 and the bottom glass core 136 are the same. Thus, in some examples, the different CTEs of the glass cores 132, 134, 136 are symmetrical across the overall thickness of the substrate core 128. That is, the arrangement or ordering of the stack of glass cores 132, 134, 136 and their associated CTEs define a symmetric sequence of CTEs from a lowermost glass core (e.g., the bottom glass core 136) to an uppermost glass core (e.g., the top glass core 132). In other examples, the different CTEs may not be symmetrical.

In addition to implementing multiple glass cores with different CTEs to reduce stress, in some examples, a buffer material 140 (e.g., adhesive material) is disposed between adjacent ones of the glass cores 132, 134, 136 to hold the glass cores together. In some such examples, the buffer material 140 has a relatively low modulus of elasticity to absorb stress resulting from thermal fluctuations and the different CTEs of the glass cores 132, 134, 136, thereby further reducing stress internal to the substrate core 128. In some examples, the buffer material is an organic dielectric material (e.g., polyimide, parylene, etc.). In some examples, the buffer material is an inorganic dielectric material (e.g., silicon oxide (SiOx), silicon nitride (SiNₓ)). In some examples, the buffer material includes a carbon doped oxide (CDO). In some examples, one or more of the layers of the buffer material 140 may be omitted such that different ones of the glass cores 132, 134, 136 are directly abutting. In some examples, the layers of the buffer material 140 include conductive material that facilitates the redistribution of electrical paths between the glass cores 132, 134, 136. Thus, the materials between the glass cores are also referred to herein as redistribution material that defines one or more buffer layers in the package substrate 110.

Although three different glass cores (e.g., the glass cores 132, 134, 136, etc.) are shown in the example substrate core 128 of FIG. 1, any other suitable number of glass cores may be implemented with corresponding CTEs to define a particular CTE gradient across the overall thickness of the substrate core 128. Thus, in some examples, only two glass cores, each with a different CTE, are employed. In other examples, more than three glass cores are employed. In some such examples, each glass core is different than every other glass core in the stack of cores. In other examples, two or more of the glass cores may have the same CTE (e.g., made from the same materials with the same composition) with at least one glass core having a different CTE than the others.

In the illustrated example of FIG. 1, each of the glass cores 132, 134, 136 is shown as having the same thickness (e.g., an approximately equal thickness, etc.). However, in some examples, the thickness of the glass cores 132, 134, 136 may differ from one another. For instance, in some examples, the middle glass core 134 is thicker than the top glass core 132 and thicker than the bottom glass core 136. In other examples, the middle glass core 134 is thinner than the top glass core 132 and thinner than the bottom glass core 136. Any suitable thickness(es) for the glass cores can be implemented to achieve a suitable CTE gradient that reduces stress to mitigate against to seware failures while also providing sufficient rigidity for the package substrate.

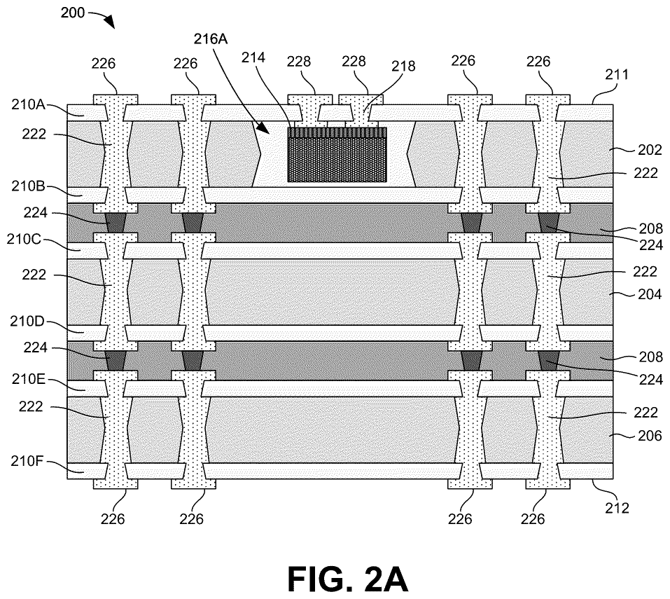

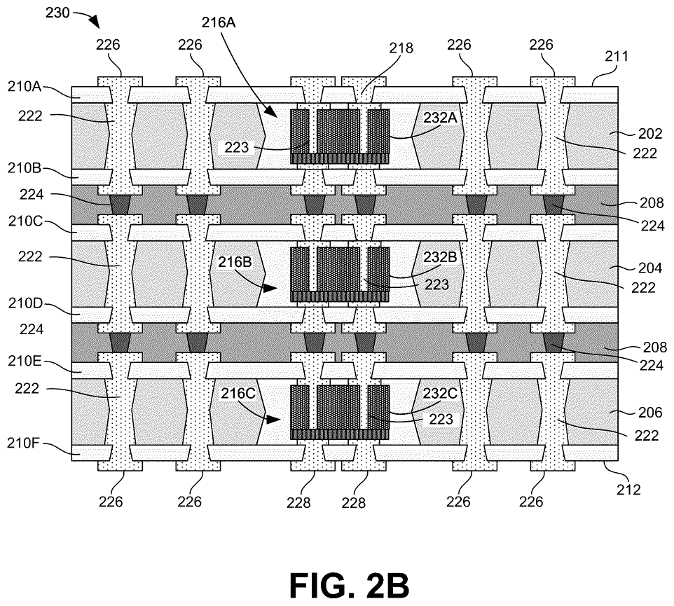

The stacking of multiple glass cores 132, 134, 136 with different CTEs as disclosed herein can serve to reduce stress that may otherwise lead to seware failures. The example substrate cores disclosed herein also include deep trench capacitors embedded therein. Example substrate cores disclosed herein include deep trench capacitors to improve power delivery to components coupled to the package substrates, such as the dies 106, 108 of FIG. 1. Some example substrate cores disclosed herein include a deep trench (e.g., disposed in, etc.) embedded in an uppermost one of the stacked glass cores. Other example substrate cores disclosed herein include one or more deep trench capacitors disposed in other ones of the stacked glass cores. Other example substrate cores disclosed herein include deep trench capacitors disposed in two or more of the stacked glass cores. Example substrate cores including embedded deep trench capacitors are described below in conjunction with FIGS. 2A-2B.

FIG. 2A illustrates an example first substrate core 200 that may be used to implement the example substrate core 128 of FIG. 1. Similar to FIG. 1, the first substrate core 200 of FIG. 2 includes an example first glass core 202, an example second glass core 204, and an example third glass core 206 that are stacked on top of one another. In this example, the glass cores 202, 204, 206 correspond to the glass cores 132, 134, 136 of FIG. 1, respectively. Thus, the glass cores 202, 204, 206 include different CTEs as described above. For instance, in some examples, the second glass core 204 (e.g., the middle glass core) has a lower CTE than either the first glass core 202 or the third glass core 206. In this example, each of the glass cores 202, 204, 206 have approximately the same thickness. In some examples, the thickness is approximately 350 micrometers (μm). In other examples, the thickness can be greater or less than 350 μm. Further, in some examples, different ones of the glass cores 202, 204, 206 can have different thicknesses. Additionally, while three glass cores are shown, in some examples, any other suitable number of glass cores (e.g., 2, 4, 5, 6, 7, etc.) may be employed. In such examples, the stack of glass cores can define any suitable CTE gradient based on differences in the CTE for each glass core in the stack. In some examples, the CTE gradient is symmetrical across the overall thickness of the first substrate core 200. In other examples, the CTE gradient may not be symmetrical.

In the illustrated example of FIG. 2A, the glass cores 202, 204, 206 are separated by intervening layers of adhesive dielectric 208 (e.g., a buffer material, an adhesive material, an adhesive layer, etc.). In some examples, the adhesive dielectric 208 includes an organic epoxy-based dielectric. However, any other suitable dielectric may additionally or alternatively be used. In some examples, the adhesive dielectric 208 couples corresponding ones of the glass cores 202, 204, 206 together. For example, the layer of the adhesive dielectric 208 between the first glass core 202 and the second glass core 204 adhesively couples the first glass core 202 to the second glass core 204, etc.

In the illustrated example of FIG. 2A, the first substrate core 200 includes an example first buffer layer 210A, an example second buffer layer 210B, an example third buffer layer 210C, an example fourth buffer layer 210D, an example fifth buffer layer 210E, and an example sixth buffer layer 210F. The buffer layers 210A, 210B, 210C, 210D, 210E, 210F includes (e,g., is comprised of, etc.) a dielectric filler material (e.g., Ajinomoto build-up film (ABF), etc.) and can include one or more conductive interconnections (e.g., vias, pads, bumps, etc.) disposed within a. The conductive interconnections of the buffer layers 210A, 210B, 210C, 210D, 210E, 210F transmit power and/or electrical signals between adjacent ones of the glass cores 202, 204, 206. In some examples, some or all of the buffer layers 210A, 210B, 210C, 210D, 210E, 210F are redistribution layers. In some such examples, the interconnections of some or all the buffer layers 210A, 210B, 210C, 210D, 210E, 210F may connect non-vertically aligned ones of the TGVs 222 and TSV 223.

In the illustrated example of FIG. 2A, the first buffer layer 210A and the sixth buffer layer 210F are on the outermost surfaces of the outermost glass cores (e.g., the first glass core 202 and third glass core 206). Thus, in the illustrated example of FIG. 2A, the first buffer layer 210A and the sixth buffer layer 210F define an example first outer surface 211 and an example second outer surface 212 of the first substrate core 200. In some examples, some or all of the buffer layers 210A, 210B, 210C, 210D, 210E, 210F are absent. In such examples, corresponding ones of the glass cores 202, 204, 206 directly abut a corresponding layer of the adhesion dielectric 208. An example substrate core in which the second buffer layer 210B, the third buffer layer 210C, the fourth buffer layer 210D, the fifth buffer layer 210E, and the sixth buffer layer 210F are absent is described below in conjunction with FIG. 2B. In some such examples, the first buffer layer 210A and the sixth buffer layer 210F shown in FIG. 2A may be omitted and/or correspond to a first layer of build-up regions (e.g., the build-up regions 130 of FIG. 1) on either side of the first substrate core 200. In such examples, the outer surfaces of the first glass core 202 and third glass core 206 define the first outer surface 211 and the second outer surface 212 of the first substrate core 200.

In the illustrated example of FIG. 2A, the first substrate core 200 includes an example deep trench capacitor 214 embedded in an example opening 216A (e.g., a cavity, etc.). The deep trench capacitor 214 includes structures for a capacitor fabricated on a semiconductor (e.g., silicon) substrate). Thus, the deep trench capacitor 214 is an example semiconductor die embedded in the opening 216A. The deep trench capacitor 214 is used to enable efficient power delivery to a fully integrated voltage regulator within a die mounted on the first substrate core 200 (e.g., the first die 106 of the IC package 100 of FIG. 1, etc.). In the illustrated example of FIG. 2A, the deep trench capacitor 214 has a smaller thickness than the first glass core 202 and is electrically coupled to a surface of the first glass core 202 via example interconnections 218. In other examples, the deep trench capacitor 214 has a same thickness as the first glass core 202 and is approximately flush with the outer surfaces of the first glass core 202. In other examples, the deep trench capacitor 214 is disposed on a spacer (e.g., a pedestal, etc.). While examples described herein are described with reference to deep trench capacitor(s) (e.g., the deep trench capacitor 214, etc.), examples disclosed herein are also applicable to other embedded semiconductor devices (e.g., EMIBs, a die, etc.).

In the illustrated example of FIG. 2A, the first substrate core 200 includes a single deep trench capacitor (e.g., the deep trench capacitor 214, etc.). In other examples, the first substrate core 200 can include additional deep trench capacitors in the first glass core 202 (e.g., two deep trench capacitors, three deep trench capacitors, etc.). In some such examples, separate deep trench capacitors are placed within the same opening 216A of the first glass core 202. In other examples, different deep trench capacitors are placed within different openings in the first glass core 202. Additionally or alternatively, the first substrate core 200 can include additional deep trench capacitors embedded in one or more opening(s) of the second glass core 204 and/or the third glass core 206. An example substrate core including deep trench capacitors embedded in the second glass core 204, and the third glass core 206 is described below in conjunction with FIG. 2B.

In the illustrated example of FIG. 2A, the glass cores 202, 204, 206 also include example first through glass vias (TGVs) 222 that are electrically coupled by additional conductive material 224 extending through the intervening layers of the adhesive dielectric 208. In the illustrated example of FIG. 2A, the TGVs 222 are adjacent to the lateral edges of the first substrate core 200. That is, in the illustrated example of FIG. 2A, the center of the first substrate core 200 does not include TGVs. In other examples, the first substrate core 200 can include other arrangements of TGVs 222 and deep trench capacitors (e.g., the deep trench capacitor 214, etc.). For example, the deep trench capacitor 214 can be disposed near one of the lateral edges and the TGVs 222 can be disposed near the center of the first substrate core 200. In such examples, like the illustrated example of FIG. 2A, the TGVs 222 are not vertically aligned with regions of the first substrate core 200 that include a deep trench capacitor (e.g., the deep trench capacitor 214, etc.). In the illustrated example of FIG. 2A, the interconnections of the buffer layers 210B, 210C, 210D, 210E couple vertically aligned ones of the TGVs 222. In other examples, the interconnections of the buffer layers 210B, 210C, 210D, 210E can redistribute (e.g., split, merge, redirect, etc.) the electrical connections between the TGVs 222. That is, the buffer layers 210B, 210C, 210D, 210E enable non-vertically aligned ones of the TGVs 222 to be electrically coupled. In some examples, the TGVs 222 are plated with the same material as used in the additional conductive material 224 (e.g., copper paste, plated copper pads, liquid metal (LM) paste, etc.). In some examples, at least some of the additional conductive material 224 may contain a different material than the TGVs 222. In the illustrated example of FIG. 2A, the first substrate core 200 includes example first conductive pads 226 that are positioned on the outer surfaces 211, 212 of the first substrate core 200 and electrically coupled to the TGVs 222 and the additional conductive material 224. In this example, the first conductive pads 226 define opposite ends of interconnects (e.g., portions of the interconnects 124 of FIG. 1) extending the full thickness of the first substrate core 200. In the illustrated example of FIG. 2A, the first substrate core 200 includes example second conductive pads 228 that are electrically coupled to the interconnections 218 of the deep trench capacitor 214. In some examples, the second conductive pads 228 can be coupled to corresponding interconnections within the build-up region 130 of FIG. 1 to enhance power distribution to dies 106, 108. In some examples, one or more of the second conductive pads 228 and one or more first conductive pads 226 can be implemented by one or more same electrical pad(s). That is, a single electrical pad can be coupled to at least one of the interconnections 218 of the deep trench capacitor 214 and at least one of the TGVs 222.

FIG. 2B illustrates an example second substrate core 230 that may be used to implement the example substrate core 128 of FIG. 1. In the illustrated example of FIG. 2B, the second substrate core 230 includes the glass cores 202, 204, 206 of FIG. 2A, the adhesive dielectric 208 of FIG. 2A, the buffer layers 210A, 210B, 210C, 210D, 210E, 210F of FIG. 2A, the outer surfaces 211, 212 of FIG. 2A, the opening 216A of FIG. 2A (referred to as the first opening 216A in conjunction with FIG. 2B), the TGVs 222 of FIG. 2A, the additional conductive material 224 of FIG. 2A, and the conductive pads 226, 228 of FIG. 2A. The second substrate core 230 of FIG. 2B is similar to the first substrate core 200 of FIG. 2A, except that the second substrate core 230 includes an example first deep trench capacitor 232A embedded in the first opening 216A of the first glass core 202, an example second deep trench capacitor 232B embedded in an example second opening 216B in the second glass core 204, and an example third deep trench capacitor 232C embedded an example third opening 216C of the third glass core 206.

In the illustrated example of FIG. 2B, the second substrate core 230 includes example through silicon vias (TSVs) 223. The TSVs 223 are similar to the first TGV 222, except as noted otherwise. In the illustrated example of FIG. 2B, the second TGVs are electrically coupled to the interconnections 218 of FIG. 2A. The TSVs 223 extend through the openings 216A, 216B, 216C in the center of the glass cores 202, 204, 206 and electrically couple the deep trench capacitors 232A, 232B, 232C in series. In other examples, the TSVs 223 can be disposed at a different location in the second substrate core 230 (e.g., depending on the position of the deep trench capacitors 232A, 232B, 232C, etc.). In the illustrated example of FIG. 2B, corresponding ones of the TSVs 223 are coupled via the additional conductive material 224. In some examples, some of the TSVs 223 are electrically coupled to the first TGVs 222 via interconnections of the buffer layers 210A, 210B, 210C, 210D, 210E, 210F.

In the illustrated example of FIG. 2B, the deep trench capacitors 232A, 232B, 232C are similar to the deep trench capacitor 214 of FIG. 2A, except that the TSVs 223 extend through the deep trench capacitors 232A, 232B, 232C. That is, the deep trench capacitors 232A, 232B, 232C include interconnections that enable the transmission of electrical power through the deep trench capacitors 232A, 232B, 232C. In other examples, the deep trench capacitors 232A, 232B, 232C do not include internal interconnects associated with the TSVs 223. In some examples, the TSVs 223 are disposed within in the openings 216A, 216B, 216C and exterior to the deep trench capacitors 232A, 232B, 232C. In some such examples, the TSVs 223 are referred to herein as through dielectric vias (TDVs). In the illustrated example of FIG. 2B, the deep trench capacitors 232A, 232B, 232C have a same size and a same shape as the deep trench capacitor 214 of FIG. 2A. In other examples, the deep trench capacitors 232A, 232B, 232C can have a different size, shape, and/or configuration than the first deep trench capacitor 214. In the illustrated example of FIG. 2C, the deep trench capacitors 232A, 232B, 232C are disposed in (e.g., embedded in, etc.) the openings 216A, 216B, 216C, respectively. In other examples, some or all of the deep trench capacitors 232A, 232B, 232C are absent. In the illustrated example of FIG. 2B, the deep trench capacitors 232A, 232B, 232C are electrically coupled in series. In other examples, the deep trench capacitors 232A, 232B, 232C can be arranged in parallel and/or any other suitable configuration. In the illustrated example of FIG. 2B, the second substrate core 230 includes an equal quantity of glass core layers (e.g., a first quantity of layers, three layers, etc.) and deep trench capacitors (e.g., a second quantity of deep trench capacitors, three deep trench capacitors, etc.). In other examples, the second substrate core 230 can include a greater quantity of deep trench capacitors than glass core layers. In some such examples, each of the glass cores 202, 204, 206 can include multiple deep trench capacitors.

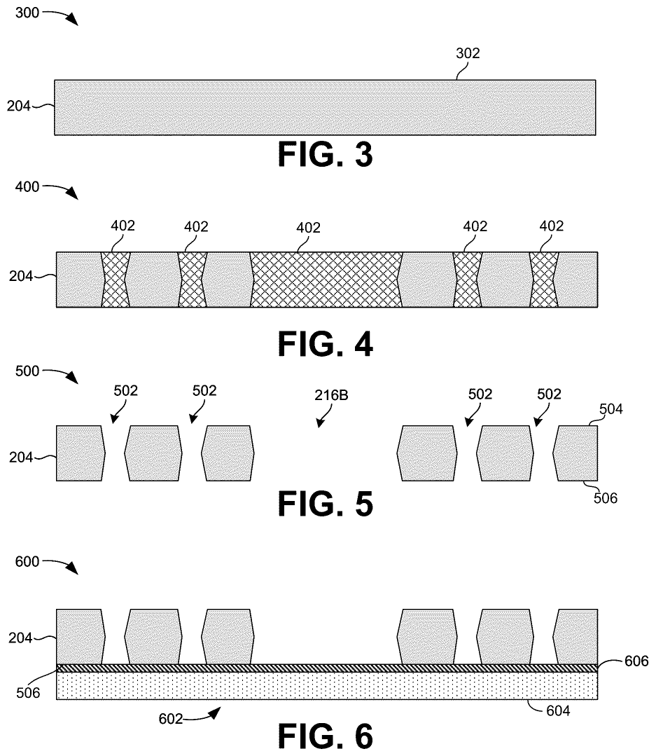

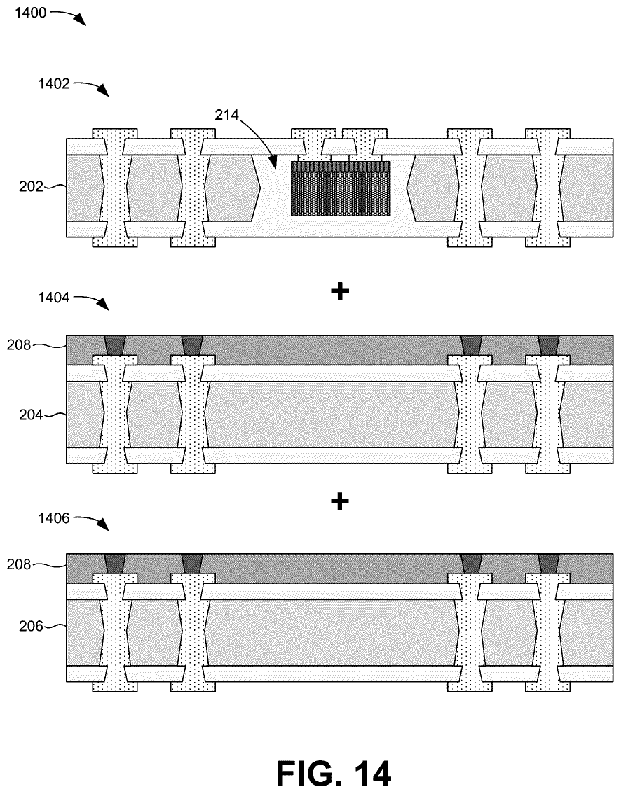

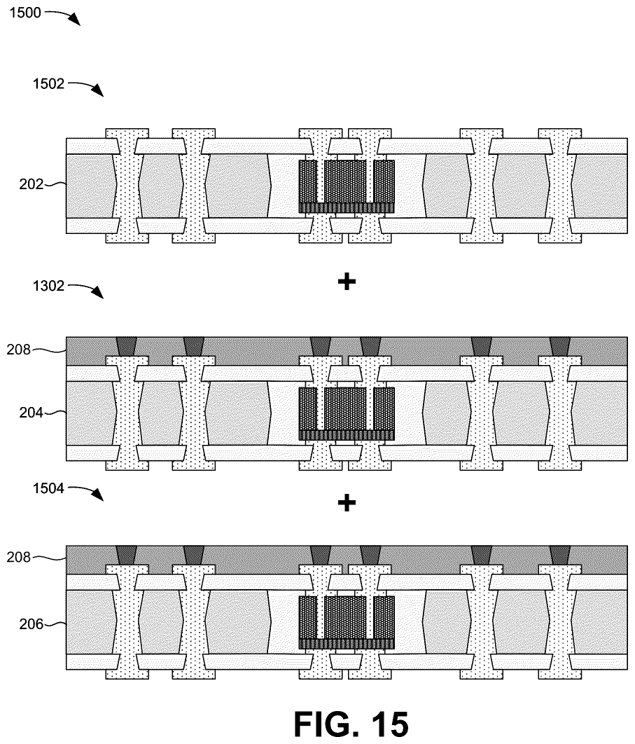

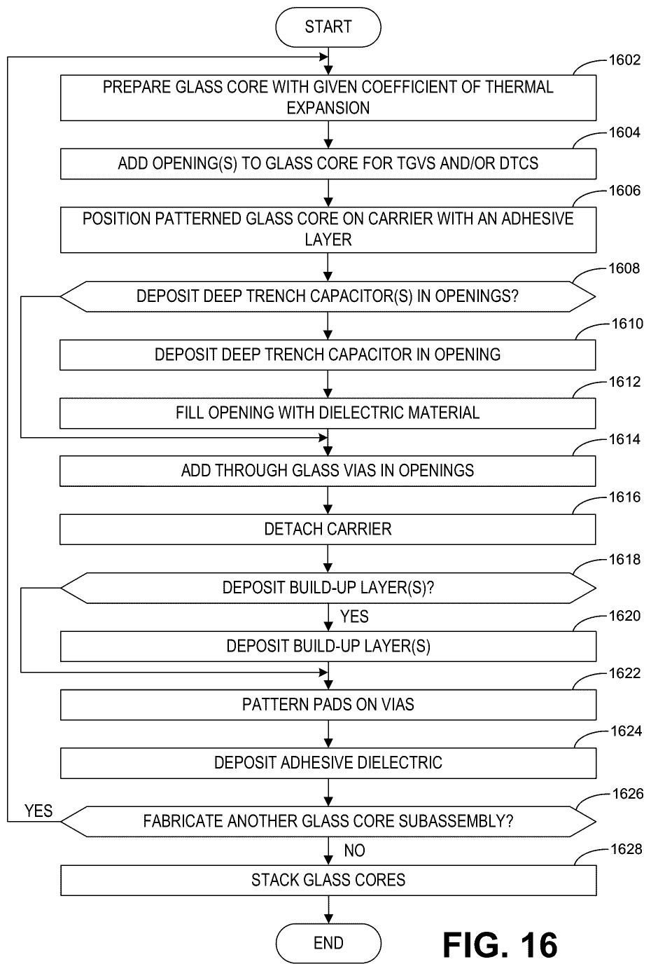

FIGS. 3-13 illustrate different stages in an example fabrication process to manufacture a glass core subassembly that can be used with the example first substrate core 200 of FIG. 2A and/or the example second substrate core 230 of FIG. 2B. As used herein, the term “glass core subassembly” refers to a glass core of a substrate core including a stack of glass cores and any associated components that are embedded therein or disposed thereon (e.g., TGVs, deep trench capacitors, buffer layers, etc.). FIG. 14 illustrates an intermediate stage in another example fabrication process to manufacture the first substrate core 200 of FIG. 2A that can follow the different intermediate stages of FIGS. 3-13. FIG. 15 illustrates an intermediate stage in another example fabrication process to manufacture the second substrate core 230 of FIG. 2B that can follow the different intermediate stages of FIGS. 3-13. It should be appreciated that other processes and/or intermediate stages can be used to manufacture the example first substrate core 200 of FIG. 2A, and/or the example second substrate core 230 of FIG. 2B. Example operations to manufacture the substrate cores 200, 230 of FIGS. 2A and 2B via some or all of the intermediate stages of FIGS. 3-13 are described below in conjunction with FIG. 16.

FIG. 3 is a cross-sectional schematic view of an example first intermediate stage 300 of the assembly/manufacturing of a glass core subassembly associated with the first substrate core 200 of FIG. 2A and the second substrate core 230 of FIG. 2B. During the first intermediate stage 300, an example glass panel 302 is provided. The glass panel 302 can correspond to the initial state of any one of the glass cores 202, 204, 206. For purposes of explanation, the glass panel 302 is shown and described as corresponding to the second glass core 204 (e.g., the middle glass core in the substrate cores 200, 230 of FIGS. 2A and 2B). In some examples, the glass panel 302 is fabricated to a thickness corresponding to the final thickness of the glass core 204. However, in some examples, the glass panel 302 is initially slightly larger than the final thickness of the second glass core 204 to enable some amount of the glass to be removed during subsequent polishing or planarization processes as discussed further below.

FIGS. 4-8 describe the formation of through glass vias (TGVs) in the second glass core 204. The intermediate stages depicted in FIGS. 4-8 illustrate the formation of TGVs on the lateral sides of the second glass core 204 (e.g., the first TGVs 222 of FIGS. 2A and 2B, etc.) and an opening in the center of the second glass core 204 (e.g., the openings 216A, 216B, 216C of FIG. 2B, etc.). If a glass core associated with a glass core subassembly that does not include a deep trench capacitor is to be fabricated (e.g., the glass cores 204, 206 in the first substrate core 200 of FIG. 2A, etc.), the processing of the center of the glass core can be omitted during the intermediate stages depicted in FIGS. 4-8. Additionally or alternatively, the first TGVs 222 can be created at another location in the second glass core 204 (e.g., in the center of the second glass core 204, etc.), depending on the planned location of the deep trench capacitors to be embedded in the second glass core 204.

FIG. 4 is a cross-sectional schematic view of an example second intermediate stage 400 of the assembly/manufacturing of a glass core subassembly associated with the first substrate core 200 of FIG. 2A and the second substrate core 230 of FIG. 2B. In some examples, the second intermediate stage 400 can occur after the first intermediate stage 300 of FIG. 3. During the second intermediate stage 400, the second glass core 204 is exposed to a laser as part of a laser induced deep etching (LIDE) process. The laser is concentrated on defined regions 402 of the glass core 204 to modify the optical and chemical properties of the glass core 204 at those regions 402.

FIG. 5 is a cross-sectional schematic view of an example third intermediate stage 500 of the assembly/manufacturing of a glass core subassembly associated with the first substrate core 200 of FIG. 2A and the second substrate core 230 of FIG. 2B. In some examples, the third intermediate stage 500 can occur after the second intermediate stage 400 of FIG. 4. During the third intermediate stage 500, the second glass core 204 is exposed to a chemical etch process to remove the material in the modified regions 402 of the glass core 204 shown in FIG. 3 to define the opening 216A and example additional openings 502 for the TGVs 222 shown in FIGS. 2A and 2B. In the illustrated example of FIG. 5, the openings 216A, 502 have a cross-sectional profile generally corresponding to an hourglass shape with the width (e.g., diameter) of the openings 216A, 502 being narrower near a midpoint of the openings between opposing first surface 504 and second surface 506 of the glass core 204. In other examples, one or more of the openings 216A, 502 may have a different cross-sectional shape. For instance, in some examples, one or more of the openings 216A, 502 may have a generally conical or tapered shape with the width (e.g., diameter) being smallest at one of the two surfaces 504, 506 of the second glass core 204 and the width (e.g., diameter) being largest at the surfaces 504, 506. In other examples, the width (e.g., diameter) of one or more of the openings 216A, 502 is approximately consistent along a full length of the openings 502 between the opposing surfaces 504, 506 of the second glass core 204.

FIG. 6 is a cross-sectional schematic view of an example fourth intermediate stage 600 of the assembly/manufacturing of a glass core subassembly associated with the first substrate core 200 of FIG. 2A and the second substrate core 230 of FIG. 2B. In some examples, the fourth intermediate stage 600 can occur after the third intermediate stage 500 of FIG. 5. During the fourth intermediate stage 600, an example conductive carrier 602 is attached to the second surface 506. In the illustrated example of FIG. 6, the conductive carrier includes a conductive layer 604 (e.g., a copper layer) and a release layer 606 (e.g., an adhesive dielectric layer).

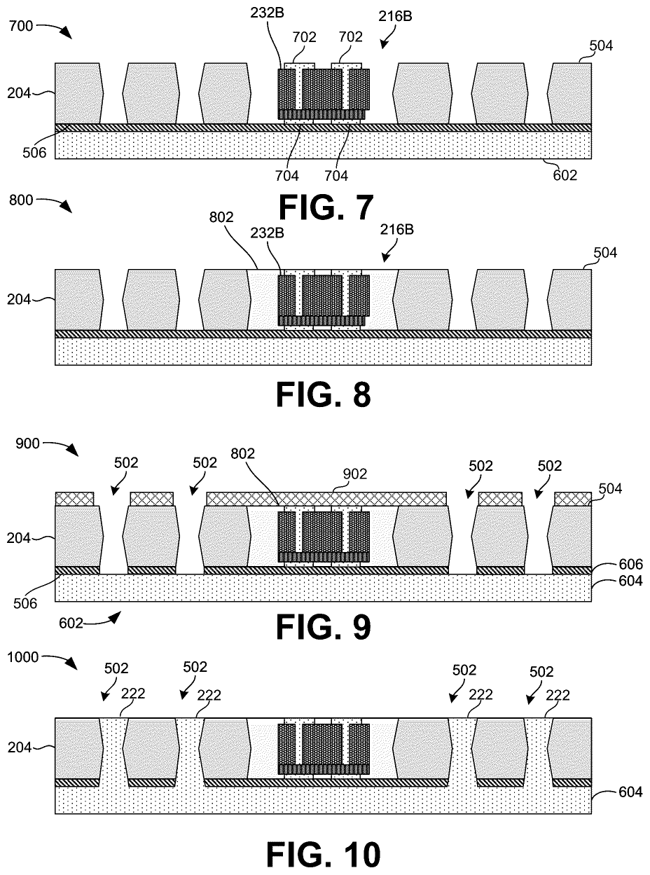

FIG. 7 is a cross-sectional schematic view of an example fifth intermediate stage 700 of the assembly/manufacturing of a glass core subassembly associated with the first substrate core 200 of FIG. 2A and the second substrate core 230 of 2B. In some examples, the fifth intermediate stage 700 can occur after the fourth intermediate stage 600 of FIG. 6. During the fifth intermediate stage 700, the first deep trench capacitor 232A is deposited within the first opening 216A onto the conductive carrier 602. In the illustrated example of FIG. 7, the first deep trench capacitor 232A includes example first DTC pads 702 and example second DTC pads 704, which enables the first deep trench capacitor 232A to be electrically coupled to external components (e.g., the dies 106, 108 of FIG. 1, etc.). In the illustrated example of FIG. 7, the second deep trench capacitor 232B is positioned within the first opening 216A such that the first DTC pads 702 are substantially flush with the first surface 504 and the second DTC pads 704 are in contact with (e.g., abut, etc.) the conductive carrier 602 and are substantially flush with the second surface 506. While FIG. 7 is described with reference to the deposition of the second deep trench capacitor 232B in the first opening 216A, other deep trench capacitors (e.g., the deep trench capacitor 214 of FIG. 2A, the first deep trench capacitor 232A, the third deep trench capacitor 232C, etc.) can be similarly deposited in a glass core. For example, the deep trench capacitor 214 of FIG. 2A can be deposited within the first opening 216A, such that the pads of the deep trench capacitor 214 abut the conductive carrier 602 and are substantially flush with the second surface 506.

FIG. 8 is a cross-sectional schematic view of an example sixth intermediate stage 800 of the assembly/manufacturing of a glass core subassembly associated with the first substrate core 200 of FIG. 2A and the second substrate core 230 of 2B. In some examples, the sixth intermediate stage 800 can occur after the fifth intermediate stage 700 of FIG. 7. During the sixth intermediate stage 800, the first opening 216A in the second glass core 204 is filled with the dielectric material 802. In the illustrated example of FIG. 8, the dielectric material 802 surrounds and/or encompasses the first deep trench capacitor 232A. In some examples, the dielectric material 802 is dispensed as a liquid or paste into the opening and subsequently cured. In some examples, any excess of the dielectric material 802 that extends beyond the first surface 504 of the second glass core 204 is removed by a polishing (e.g., a chemical mechanical planarization (CMP), etc.) process. In some examples, this polishing process slightly thins the second glass core 204.

FIG. 9 is a cross-sectional schematic view of an example seventh intermediate stage 900 of the assembly/manufacturing of a glass core subassembly associated with the first substrate core 200 of FIG. 2A and the second substrate core 230 of 2B. In some examples, the seventh intermediate stage 900 can occur after the sixth intermediate stage 800 of FIG. 8. During the seventh intermediate stage 900, an example mask 902 (e.g., via photolithography) is deposited to cover the first surface 504 except for the openings 502 of the glass core. Further, the stage of fabrication represented in FIG. 9 is after an etching process (e.g., a plasma etch, a dry etch) to remove portions of the release layer 606 exposed within the openings 502 of the glass core 204, thereby exposing the underlying conductive layer 604. The mask 902 protects the dielectric material 802 during the etching process.

FIG. 10 is a cross-sectional schematic view of an example eighth intermediate stage 1000 of the assembly/manufacturing of a glass core subassembly associated with the first substrate core 200 of FIG. 2A and the second substrate core 230 of 2B. In some examples, the eighth intermediate stage 1000 can occur after the seventh intermediate stage 900 of FIG. 9. During the eighth intermediate stage 1000, a conductive material (e.g., copper, etc.) is deposited (e.g., plated, etc.) within the openings 502 to define the TGVs 222 extending through the second glass core 204. In this example, the TGVs 222 are plated up from the exposed portions of the conductive layer 604. As such, in this example, there is no seed layer deposited along the walls of the openings 502 prior to the plating process. However, in other examples, a seed layer may be used to facilitate the plating of the TGVs 222.

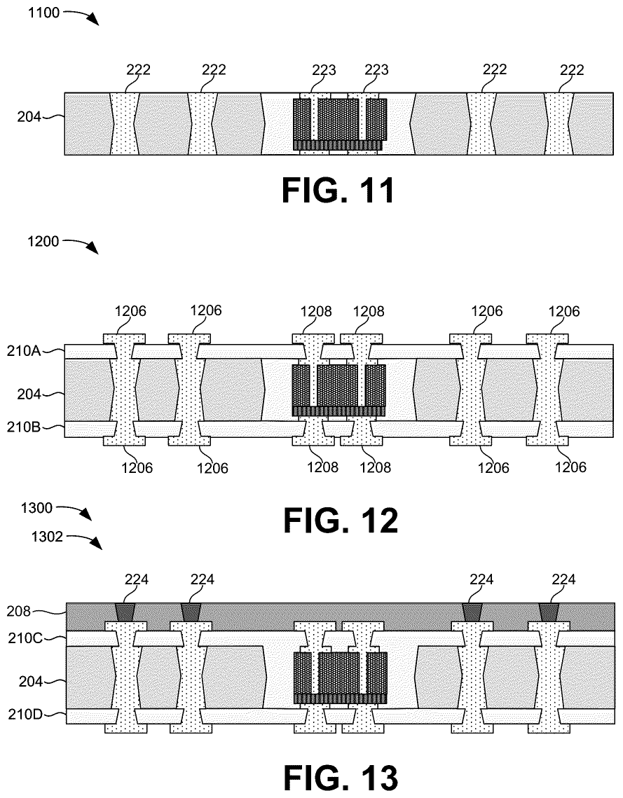

FIG. 11 is a cross-sectional schematic view of an example ninth intermediate stage 1100 of the assembly/manufacturing of a glass core subassembly associated with the first substrate core 200 of FIG. 2A and the second substrate core 230 of 2B. In some examples, the ninth intermediate stage 1100 can occur after the eighth intermediate stage 1000 of FIG. 10. During the ninth intermediate stage 1100, the conductive carrier 602, including both the conductive layer 604 and the release layer 606 is removed. In some examples, the second surface 506 of the glass core undergoes a polishing process (e.g., a CMP process, etc.) to make the TGVs 222, and TSVs 223 flush with the second surface 506. In some examples, the second glass core 204 also undergoes a cleaning process to remove any residue materials.

FIG. 12 is a cross-sectional schematic view of an example tenth intermediate stage 1200 of the assembly/manufacturing of a glass core subassembly associated with the first substrate core 200 of FIG. 2A and the second substrate core 230 of FIG. 2B. In some examples, the tenth intermediate stage 1200 can occur after the ninth intermediate stage 1100 of FIG. 11. During the tenth intermediate stage 1200, an example third buffer layer 210C and an example fourth buffer layer 210D have been deposited on the first surface 504 and the second surface 506 of the second glass core 204, respectively. The buffer layers 210C, 210D include (e.g., are composed of, etc.) a dielectric material, such as ABF, and conductive material, such as copper. In the illustrated example, the buffer layers 210C, 210D have been patterned such that the TGVs 222 and TSVs 223 extend through the buffer layers 210C, 210D. For example, the buffer layers 210C, 210D can be drilled to create openings aligned with the TGVs 222 and TSVs 223 and conductive material can be disposed in the created openings.

Additionally, during the tenth intermediate stage 1200, example first pads 1206 and example second pads 1208 are patterned on the third buffer layer 210C and the fourth buffer layer 210D. In the illustrated example of FIG. 12, the first pads 1206 are patterned on the buffer layers 210A, 210B to be aligned with the first TGVs 222 and the second pads 1208 are patterned on the buffer layers 210A, 210B to be aligned with the TSVs 223. In some examples, the pads 1206, 1208 are deposited via lithography. Additionally or alternatively, the pads 1206, 1208 can be deposited via another suitable process (e.g., atomic layer deposition (ALD), chemical vapor deposition (CVD), electroplating, etc.) or a combination thereof.

FIG. 13 is a cross-sectional schematic view of an example eleventh intermediate stage 1300 of the assembly/manufacturing of an example first glass core subassembly 1302 associated with the first substrate core 200 of FIG. 2A and the second substrate core 230 of FIG. 2B. In some examples, the eleventh intermediate stage 1300 can occur after the tenth intermediate stage 1200 of FIG. 12. During the eleventh intermediate stage 1300, the adhesive dielectric 208 is applied on the first buffer layer 210A. Additionally, during the eleventh intermediate stage 1300, the additional conductive material 224 (e.g., a liquid metal, copper paste, etc.) is deposited between portions of the interfacing surfaces defined by a conductive material to electrically couple the conductive material in the stack. In other examples, the intermediate stage 1300 is omitted. In some such examples, adjacent glass core subassemblies in a stack can be coupled via another method (e.g., fusion bonding, etc.). After the execution of the processes associated with intermediate stage 1300, the fabrication of an example first glass core subassembly 1302 is completed.

FIG. 14 is a cross-sectional schematic view of an example twelfth intermediate stage 1400 associated with the assembly/manufacturing of the first substrate core 200 of FIG. 2A. In some examples, the twelfth intermediate stage 1400 can occur after the fabrication of an example second glass core subassembly 1402, an example third glass core subassembly 1404, and an example fourth glass core subassembly 1406. The glass core subassemblies 1402, 1404, 1406 are similar to the first glass core subassembly 1302 of FIG. 13, except as noted otherwise. In the illustrated example of FIG. 14, the second glass core subassembly 1402, the third glass core subassembly 1404, and the fourth glass core subassembly 1406 include the first glass core 202 of FIG. 2A, the second glass core 204 of FIG. 2A, and the third glass core 206 of FIG. 2A, respectively.

In some examples, each of the glass core subassemblies 1402, 1404, 1406 can be manufactured via some or all the intermediate stages 300, 400, 500, 600, 700, 800, 900, 1000, 1100, 1200, 1300 of FIGS. 3-13. For example, the first glass core subassembly 1302 can be manufactured via each of the intermediate stages 300, 400, 500, 600, 700, 800, 900, 1000, 1100, 1200 of FIGS. 3-12 (e.g., the deposition of the adhesion dielectric 208 and the additional conductive material 224 during the intermediate stage 1300 of FIG. 13 is omitted, etc.). In some such examples, the deep trench capacitor 214 of FIG. 2A is deposited in the first opening 216A during the execution of intermediate stage 700 of FIG. 7. The third glass core subassembly 1404 and the fourth glass core subassembly 1406 can be manufactured can be manufactured via the intermediate stages 300, 400, 500, 600, 900, 1100, 1200 of FIGS. 3-6, 9, 11, and 12 (e.g., the deposition of a deep trench capacitor, such as the deep trench capacitor 214, during the intermediate stage 700 of FIG. 7 and subsequent processing during the intermediate stage 800 of FIG. 8 are omitted). In other examples, the glass core subassemblies 1402, 1404, 1406 of FIG. 14 can be manufactured via any other suitable process. During the twelfth intermediate stage 1400, the three glass cores 202, 204, 206 are assembled or stacked together by combining or joining the glass core subassemblies 1402, 1404, 1406. The result of combining or joining the glass core subassemblies 1402, 1404, 1406 produces the first substrate core 200 of FIG. 2A.

FIG. 15 is a cross-sectional schematic view of an example thirteenth intermediate stage 1500 associated with the assembly/manufacturing of the second substrate core 230 of FIG. 2B. In some examples, the thirteenth intermediate stage 1500 can occur after the fabrication of the first glass core subassembly 1302 of FIG. 13, an example fourth glass core subassembly 1502, and an example fifth glass core subassembly 1504. In the illustrated example of FIG. 15, the fourth glass core subassembly 1502 and the fifth glass core subassembly 1504 include the second glass core 204 of FIG. 2B, and the third glass core 206 of FIGS. 2A and 2B, respectively. The fourth glass core subassembly 1502 can be manufactured via each of the intermediate stages 300, 400, 500, 600, 700, 800, 900, 1000, 1100, 1200 of FIGS. 3-12 (e.g., the deposition of the adhesion dielectric 208 and the additional conductive material 224 during the intermediate stage 1300 of FIG. 13 is omitted, etc.). The fifth glass core subassembly 1504 can be manufactured via each of the intermediate stages 300, 400, 500, 600, 700, 800, 900, 1000, 1100, 1200, 1300 of FIGS. 3-13. In other examples, the glass core subassemblies 1302, 1502, 1504 of FIG. 15 can be manufactured via any other suitable process. During the thirteenth intermediate stage 1500, the three glass cores 202, 204, 206 are assembled or stacked together by combining or joining the glass core subassemblies 1302, 1502, 1504. The glass core subassemblies 1302, 1502, 1504 of FIG. 15 can be stacked/assembled in a manner similar to the stacking of the glass core subassemblies 1402, 1404, 1406 of FIG. 14 described in conjunction with FIG. 14. The result of combining or joining the glass core subassemblies 1302, 1502, 1504 produces the second substrate core 230 of FIG. 2B.

FIG. 16 is a flowchart representative of an example method that may be performed to fabricate any one of the example first substrate core 200 of FIG. 2A and the second substrate core 230 of FIG. 2B via the intermediate stages 300, 400, 500, 600, 700, 800, 900, 1000, 1100, 1200, 1300, 1400, 1500 of FIGS. 3-15. In some examples, some or all of the operations outlined in the example method of FIG. 16 are performed automatically by equipment that is programmed to perform the operations. Although the example method is described with reference to the flowchart illustrated in FIG. 16, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 16 begins at block 1602 by preparing a glass core (e.g., any one of the glass cores 202, 204, 206) with a given coefficient of thermal expansion (CTE). For example, the coefficients of thermal expansion of each of the glass cores 202, 204, 206 can be tuned by tailoring (e.g., varying, changing, etc.) the composition of the glass of each of the layers. For example, the coefficients of thermal expansion of each of the glass cores 202, 204, 206 can be tailored by varying the relative proportions of Al₂O₃, B₂O₃, Li₂O, Na₂O, K₂O, Sb₂O₃, and/or other additives in each of the layers and/or via processing variations (e.g., lamination cladding, thermal treatment, etc.). In some examples, the composition of materials used in the glass core is selected to achieve the CTE intended for a particular layer of glass within an overall substrate core that includes multiple glass cores stacked together. In some examples, the composition of materials used in the glass core is selected to achieve the CTE intended for a particular layer of glass within an overall substrate core that includes multiple glass cores stacked together. The point of fabrication after completion of block 1602 corresponds to the structure of the first intermediate stage 300 of FIG. 3. At block 1604, the example method includes adding openings through the glass core. For example, openings corresponding to the first TGVs 222 and/or one of the openings 216A, 216B, 216C can be formed in the glass core 204. In some examples, if the glass core subassembly is not to include a DTC, an opening in the center of the center of the second glass core 204 (e.g., one of the openings 216A, 216B, 216C, etc.) is not added. For example, the openings can be formed via laser exposure and/or etching. The point of fabrication after completion of block 1602 corresponds to the structure of the third intermediate stage 500 of FIG. 5. At block 1606, the example method involves attaching a carrier to the glass core 202. For example, the second glass core 204 can be attached to the conductive carrier 602 of FIG. 6 via the release layer 606. The point of fabrication after completion of block 1606 corresponds to the structure of the fourth intermediate stage 600 of FIG. 6.

At block 1608, the method includes determining if one or more deep trench capacitor(s) (e.g., one of the deep trench capacitors 214, 232A, 232B, 232C, etc.) are to be deposited in the second opening 216B of the second glass core 204. If a deep trench capacitor is to be deposited on the second glass core 204, the method advances to block 1610. If a deep trench capacitor is not to be deposited in the second opening 216B of the second glass core 204, the method advances to block 1614. At block 1610, the deep trench capacitor 232B is deposited in the opening 216B onto the carrier 602. For example, the second deep trench capacitor 232B (and/or another one of the deep trench capacitors 214, 232A, 232B of FIGS. 2A and 2B, etc.) can be deposited in the second opening 216B via a mechanical deposition technique (e.g., pick-and-place, etc.) In other examples, the second deep trench capacitor 232B can be deposited in the opening 216A, 216B, 216C via another technique and/or fabricated therein via a plurality of semiconductor manufacturing techniques. The point of fabrication after completion of block 1610 corresponds to the structure of the fifth intermediate stage 700 of FIG. 7. At block 1612, the second opening 216B in the second glass core 204 is filled with the dielectric material 802. For example, the dielectric material 802 can be deposited in the second opening 216B such that the dielectric material surrounds and/or encompasses the second deep trench capacitor 232B. The point of fabrication after completion of block 1612 corresponds to the structure of the seventh intermediate stage 900 of FIG. 9.

At block 1614, a conductive material is deposited into the openings to first TGVs 222 through the second glass core 204. For example, the TGVs 222 can be formed in the openings via electroplating from a conductive layer of the attached carrier (e.g., fully bottom-up plating, partially bottom-up plating, etc.). In some examples, a mask (e.g., the mask 902 of FIG. 9, etc.) can be deposited on the second glass core 204 to shield other components of the glass core 204 during deposition of the conductive material. The point of fabrication after completion of block 1614 corresponds to the structure of the eighth intermediate stage 1000 of FIG. 10. At block 1616, the example method involves the detachment of the conductive carrier 602 from the second glass core 204. In some examples, the second glass core 204 is polished and cleaned after the detachment of the conductive carrier 602. The point of fabrication after completion of block 1616 corresponds to the structure of the ninth intermediate stage 1100 of FIG. 11.

At block 1618, the method includes determining if one or more build-up layer(s) (e.g., the buffer layers 210A, 210B, etc.) are to be deposited on the second glass core 204. If a build-up layer is to be deposited on the second glass core 204, the method advances to block 1620. If a build-up layer is not to be deposited on the second glass core 204, the method advances to block 1622. At block 1620, the method involves depositing buffer layers on the top surface and/or bottom surface of the second glass core 204. For example, the materials for additional redistribution layer(s) (e.g., the dielectric layers, interconnections, etc.) can be deposited on the second glass core 204. In some examples, the buffer layers 210A, 210B can be processed (e.g., drilled, patterned via lithography, etc.) to form openings aligned with the TGVs 222 and TSVs 223. In some such examples, conductive material can be disposed therein to extend the TGVs to the outer surfaces of the buffer layers 210A, 210B.

At block 1622, the method involves the patterning of pads on the TGVs 222 and TSVs 223. For example, the first pads 1206 of FIG. 12 can be patterned on the buffer layers 210A, 210B to be aligned with the TGVs 222 and the second pads 1208 of FIG. 12 can be patterned on the buffer layers 210A, 210B to be aligned with the TSV 223. In some examples, the pads 1206, 1208 are deposited via lithography. Additionally or alternatively, the pads 1206, 1208 can be deposited via another suitable process (e.g., ALD, CVD, electroplating, etc.) or a combination thereof. The point of fabrication after completion of block 1622 corresponds to the structure of the tenth intermediate stage 1200 of FIG. 12.

At block 1624, the method involves the deposition of the adhesive dielectric 208. For example, the adhesive dielectric 208 can be deposited (e.g., via spin-coating, via lamination, etc.) on the first buffer layer 210A. In some examples, the additional conductive material 224 (e.g., a liquid metal, copper paste, etc.) is deposited between portions of the interfacing surfaces defined by a conductive material to electrically couple the conductive material in the stack. The point of fabrication after completion of block 1626 corresponds to the structure of the eleventh intermediate stage 1300 of FIG. 13.

At block 1626, the example method involves determining whether to fabricate another glass core assembly (e.g., the glass core subassemblies 1302, 1402, 1404, 1406, 1502, 1504, etc.). If so, the process returns to block 1602 to repeat the process for a different glass core subassembly. In some examples, the different glass core subassembly can be constructed with a different CTE, include a different configuration of deep trench capacitors (e.g., the absence or presence thereof, etc.), and/or include a different configuration of buffer layers. In some examples, the separate iterations through the example process can be performed in parallel rather than sequentially. Once there are no further glass core assemblies to fabricate, the example process advances to block 1628 that involves stacking (e.g., combining, etc.) the glass core assemblies. In some examples, the glass core assemblies, as completed up to block 1626, are directly joined together) to form a corresponding one of the substrate cores 200, 230 of FIGS. 2A-2B. The completion of the example process of FIG. 16 results in a completed substrate core (e.g., any one of the substrate cores 200, 230, etc.). Thereafter, the completed substrate core may undergo any suitable subsequent processing (e.g., adding build-up layers, attaching one or more dies, and implementing other packaging processes).

Although example operations are described with reference to the flowchart illustrated in FIG. 16, many other methods of assembling/manufacturing the substrate cores 200, 230 of FIGS. 2A and 2B may alternatively be used. For example, the order of execution of the blocks may be changed, and/or some of the blocks described may be changed, eliminated, or combined.

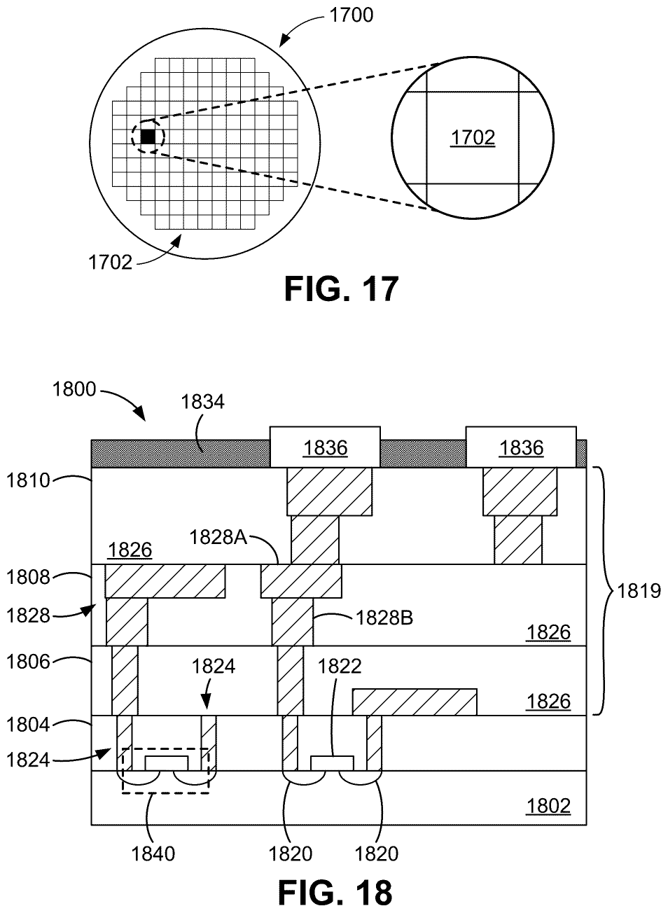

The example IC package 100 of FIG. 1 (e.g., with any of the example substrate cores 200, 230, etc.) disclosed herein may be included in any suitable electronic component. FIGS. 17-20 illustrate various examples of apparatus that may include or be included in the IC package 100 disclosed herein.

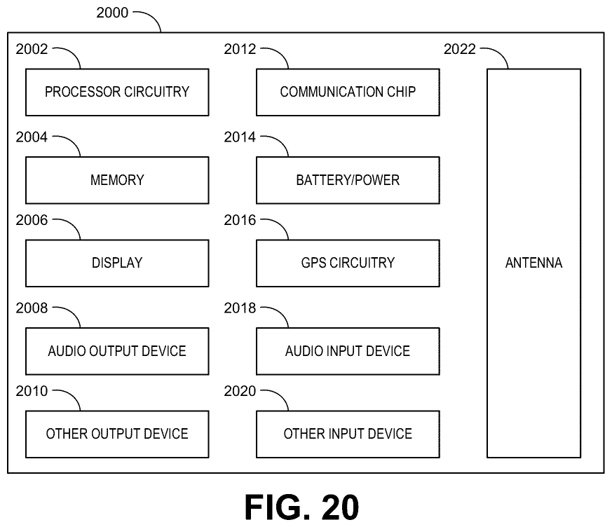

FIG. 17 is a top view of a wafer 1700 and dies 1702 that may be included in the IC package 100 of FIG. 1 (e.g., as any suitable ones of the dies 106, 108). The wafer 1700 includes semiconductor material and one or more dies 1702 having circuitry. Each of the dies 1702 may be a repeating unit of a semiconductor product. After the fabrication of the semiconductor product is complete, the wafer 1700 may undergo a singulation process in which the dies 1702 are separated from one another to provide discrete “chips.” The die 1702 includes one or more transistors (e.g., some of the transistors 1840 of FIG. 18, discussed below), supporting circuitry to route electrical signals to the transistors, passive components (e.g., traces, resistors, capacitors, inductors, and/or other circuitry), and/or any other components. In some examples, the die 1702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die (e.g., the die 1702, etc.). For example, a memory array of multiple memory circuits may be formed on a same (e.g., the die 1702, etc.) as programmable circuitry (e.g., the processor circuitry 2002 of FIG. 20) and/or other logic circuitry. Such memory may store information for use by the programmable circuitry. The example IC package 100 disclosed herein may be manufactured using a die-to-wafer assembly technique in which some dies are attached to a wafer 1700 that includes others of the dies, and the wafer 1700 is subsequently singulated.

FIG. 18 is a cross-sectional side view of an IC device 1900 that may be included in the example IC package 100 (e.g., in any one of the dies 106, 108). One or more of the IC devices 1800 may be included in one or more dies 1702 (FIG. 17). The IC device 1800 may be formed on a die substrate 1802 (e.g., the wafer 1700 of FIG. 17) and may be included in a die (e.g., the die 1702 of FIG. 17). The die substrate 1802 may be a semiconductor substrate including semiconductor materials including, for example, n-type or p-type materials systems (or a combination of both). The die substrate 1802 may include, for example, a crystalline substrate formed using a bulk silicon or a silicon-on-insulator (SOI) substructure. In some examples, the die substrate 1802 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1802. Although a few examples of materials from which the die substrate 1802 may be formed are described here, any material that may serve as a foundation for an IC device 1800 may be used. The die substrate 1802 may be part of a singulated die (e.g., the dies 1702 of FIG. 17) or a wafer (e.g., the wafer 1700 of FIG. 17).

The IC device 1800 may include one or more device layers 1804 disposed on and/or above the die substrate 1802. The device layer 1804 may include features of one or more transistors 1840 (e.g., metal oxide semiconductor field-effect transistors (MOSFETs)) formed on the die substrate 1802. The device layer 1804 may include, for example, one or more source and/or drain (S/D) regions 1820, a gate 1822 to control current flow between the S/D regions 1820, and one or more S/D contacts 1824 to route electrical signals to/from the S/D regions 1820. The transistors 1840 may include additional features not depicted for the sake of clarity, such as device isolation regions, gate contacts, and the like. The transistors 1840 are not limited to the type and configuration depicted in FIG. 18 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1840 may include a gate 1822 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1840 along the source-channel-drain direction, the gate electrode may include a U-shaped structure that includes a bottom portion substantially parallel to the surface of the die substrate 1802 and two sidewall portions that are substantially perpendicular to the top surface of the die substrate 1802. In other examples, at least one of the metal layers that form the gate electrode may be a planar layer that is substantially parallel to the top surface of the die substrate 1802 and does not include sidewall portions substantially perpendicular to the top surface of the die substrate 1802. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1820 may be formed within the die substrate 1802 adjacent to the gate 1822 of corresponding transistor(s) 1840. The S/D regions 1820 may be formed using an implantation/diffusion process or an etching/deposition process, for example. In the former process, dopants such as boron, aluminum, antimony, phosphorous, or arsenic may be ion-implanted into the die substrate 1802 to form the S/D regions 1820. An annealing process that activates the dopants and causes them to diffuse farther into the die substrate 1802 may follow the ion-implantation process. In the latter process, the die substrate 1802 may first be etched to form recesses at the locations of the S/D regions 1820. An epitaxial deposition process may then be carried out to fill the recesses with material that is used to fabricate the S/D regions 1820. In some implementations, the S/D regions 1820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1820 may be formed using one or more alternate semiconductor materials such as germanium or a group III-V material or alloy. In further examples, one or more layers of metal and/or metal alloys may be used to form the S/D regions 1820.

Electrical signals, such as power and/or input/output (I/O) signals, may be routed to and/or from the devices (e.g., transistors 1840) of the device layer 1804 through one or more interconnect layers disposed on the device layer 1804 (illustrated in FIG. 18 as interconnect layers 1806-1810). For example, electrically conductive features of the device layer 1804 (e.g., the gate 1822 and the S/D contacts 1824) may be electrically coupled with the interconnect structures 1828 of the interconnect layers 1806-1810. The one or more interconnect layers 1806-1810 may form a metallization stack (also referred to as an “ILD stack”) 1819 of the IC device 1800.

The interconnect structures 1828 may be arranged within the interconnect layers 1806-1810 to route electrical signals according to a wide variety of designs (in particular, the arrangement is not limited to the particular configuration of interconnect structures 1828 depicted in FIG. 18). Although a particular number of interconnect layers 1806-1810 is depicted in FIG. 18, examples of the present disclosure include IC devices having more or fewer interconnect layers than depicted.

In some examples, the interconnect structures 1828 may include lines 1828A and/or vias 1828B filled with an electrically conductive material such as a metal. The lines 1828A may be arranged to route electrical signals in a direction of a plane that is substantially parallel with a surface of the die substrate 1802 upon which the device layer 1804 is formed. For example, the lines 1828A may route electrical signals in a direction in and/or out of the page from the perspective of FIG. 18. The vias 1828B may be arranged to route electrical signals in a direction of a plane that is substantially perpendicular to the surface of the die substrate 1802 upon which the device layer 1804 is formed. In some examples, the vias 1828B may electrically couple lines 1828A of different interconnect layers 1806-1810 together.

The interconnect layers 1806-1810 may include a dielectric material 1826 disposed between the interconnect structures 1828, as shown in FIG. 18. In some examples, the dielectric material 1826 disposed between the interconnect structures 1828 in different ones of the interconnect layers 1806-1810 may have different compositions; in other examples, the composition of the dielectric material 1826 between different interconnect layers 1806-1810 may be the same.

A first interconnect layer 1806 (referred to as Metal 1 or “M1”) may be formed directly on the device layer 1804. In some examples, the first interconnect layer 1806 may include lines 1828A and/or vias 1828B, as shown. The lines 1828A of the first interconnect layer 1806 may be coupled with contacts (e.g., the S/D contacts 1824) of the device layer 1804.

A second interconnect layer 1808 (referred to as Metal 2 or “M2”) may be formed directly on the first interconnect layer 1806. In some examples, the second interconnect layer 1808 may include vias 1828B to couple the lines 1828A of the second interconnect layer 1808 with the lines 1828A of the first interconnect layer 1806. Although the lines 1828A and the vias 1828B are structurally delineated with a line within each interconnect layer (e.g., within the second interconnect layer 1808) for the sake of clarity, the lines 1828A and the vias 1828B may be structurally and/or materially contiguous (e.g., simultaneously filled during a dual-damascene process) in some examples.

A third interconnect layer 1810 (referred to as Metal 3 or “M3”) (and additional interconnect layers, as desired) may be formed in succession on the second interconnect layer 1808 according to similar techniques and/or configurations described in connection with the second interconnect layer 1808 or the first interconnect layer 1806. In some examples, the interconnect layers that are “higher up” in the metallization stack 1819 in the IC device 1800 (i.e., further away from the device layer 1804) may be thicker.

The IC device 1800 may include a solder resist material 1834 (e.g., polyimide or similar material) and one or more conductive contacts 1836 formed on the interconnect layers 1806-1810. In FIG. 18, the conductive contacts 1836 are illustrated as taking the form of bond pads. The conductive contacts 1836 may be electrically coupled with the interconnect structures 1828 and configured to route the electrical signals of the transistor(s) 1840 to other external devices. For example, solder bonds may be formed on the one or more conductive contacts 1836 to mechanically and/or electrically couple a chip including the IC device 1800 with another component (e.g., a circuit board). The IC device 1800 may include additional or alternate structures to route the electrical signals from the interconnect layers 1806-1810; for example, the conductive contacts 1836 may include other analogous features (e.g., posts) that route the electrical signals to external components.

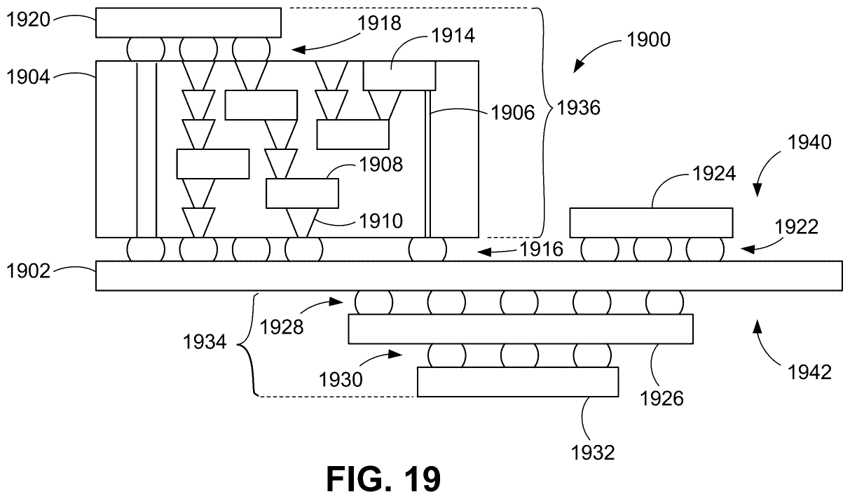

FIG. 19 is a cross-sectional side view of an IC device assembly 1900 that may include the IC package 100 disclosed herein. In some examples, the IC device assembly corresponds to the IC package 100. The IC device assembly 1900 includes a number of components disposed on a circuit board 1902 (which may be, for example, a motherboard). The IC device assembly 1900 includes components disposed on a first face 1940 of the circuit board 1902 and an opposing second face 1942 of the circuit board 1902; generally, components may be disposed on one or both faces 1940 and 1942. Any of the IC packages discussed below with reference to the IC device assembly 1900 may take the form of the example IC package 100 of FIG. 1.

In some examples, the circuit board 1902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1902. In other examples, the circuit board 1902 may be a non-PCB substrate.

The IC device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), male and female portions of a socket, an adhesive, an underfill material, and/or any other suitable electrical and/or mechanical coupling structure.

The package-on-interposer structure 1936 may include an IC package 1920 coupled to an interposer 1904 by coupling components 1918. The coupling components 1918 may take any suitable form for the application, such as the forms discussed above with reference to the coupling components 1916. Although a single IC package 1920 is shown in FIG. 19, multiple IC packages may be coupled to the interposer 1904; indeed, additional interposers may be coupled to the interposer 1904. The interposer 1904 may provide an intervening substrate used to bridge the circuit board 1902 and the IC package 1920. The IC package 1920 may be or include, for example, a die (the die 1702 of FIG. 17), an IC device (e.g., the IC device 1800 of FIG. 18), or any other suitable component. Generally, the interposer 1904 may spread a connection to a wider pitch or reroute a connection to a different connection. For example, the interposer 1904 may couple the IC package 1920 (e.g., a die) to a set of BGA conductive contacts of the coupling components 1916 for coupling to the circuit board 1902. In the example illustrated in FIG. 19, the IC package 1920 and the circuit board 1902 are attached to opposing sides of the interposer 1904; in other examples, the IC package 1920 and the circuit board 1902 may be attached to a same side of the interposer 1904. In some examples, three or more components may be interconnected by way of the interposer 1904.

In some examples, the interposer 1904 may be formed as a PCB, including multiple metal layers separated from one another by layers of dielectric material and interconnected by electrically conductive vias. In some examples, the interposer 1904 may be formed of an epoxy resin, a fiberglass-reinforced epoxy resin, an epoxy resin with inorganic fillers, a ceramic material, or a polymer material such as polyimide. In some examples, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through-silicon vias (TSVs) 1906. The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art.

The IC device assembly 1900 may include an IC package 1924 coupled to the first face 1940 of the circuit board 1902 by coupling components 1922. The coupling components 1922 may take the form of any of the examples discussed above with reference to the coupling components 1916, and the IC package 1924 may take the form of any of the examples discussed above with reference to the IC package 1920.

The IC device assembly 1900 illustrated in FIG. 19 includes a package-on-package structure 1934 coupled to the second face 1942 of the circuit board 1902 by coupling components 1928. The package-on-package structure 1934 may include a first IC package 1926 and a second IC package 1932 coupled together by coupling components 1930 such that the first IC package 1926 is disposed between the circuit board 1902 and the second IC package 1932. The coupling components 1928, 1930 may take the form of any of the examples of the coupling components 1916 discussed above, and the IC packages 1926, 1932 may take the form of any of the examples of the IC package 1920 discussed above. The package-on-package structure 1934 may be configured in accordance with any of the package-on-package structures known in the art.

FIG. 20 is a block diagram of an example electrical device 2000 that may include one or more of the example IC package 100. For example, any suitable ones of the components of the electrical device 2000 may include one or more of the device assemblies 1900, IC devices 1800, or dies 1702 disclosed herein, and may be arranged in the example IC package 100. A number of components are illustrated in FIG. 20 as included in the electrical device 2000, but any one or more of these components may be omitted or duplicated, as suitable for the application. In some examples, some or all of the components included in the electrical device 2000 may be attached to one or more motherboards. In some examples, some or all of these components are fabricated onto a single system-on-a-chip (SoC) die.

Additionally, in various examples, the electrical device 2000 may not include one or more of the components illustrated in FIG. 20, but the electrical device 2000 may include interface circuitry for coupling to the one or more components. For example, the electrical device 2000 may not include a display 2006, but may include display interface circuitry (e.g., a connector and driver circuitry) to which a display 2006 may be coupled. In another set of examples, the electrical device 2000 may not include an audio input device 2018 (e.g., microphone) or an audio output device 2008 (e.g., a speaker, a headset, earbuds, etc.), but may include audio input or output device interface circuitry (e.g., connectors and supporting circuitry) to which an audio input device 2018 or audio output device 2008 may be coupled.

The electrical device 2000 may include programmable circuitry 2002 (e.g., one or more processing devices). The programmable circuitry 2002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2004 may include memory that shares a die with the programmable circuitry 2002. This memory may be used as cache memory and may include embedded dynamic random access memory (eDRAM) or spin transfer torque magnetic random access memory (STT-MRAM).

In some examples, the electrical device 2000 may include a communication chip 2012 (e.g., one or more communication chips). For example, the communication chip 2012 may be configured for managing wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other examples. The electrical device 2000 may include an antenna 2022 to facilitate wireless communications and/or to receive other wireless communications (such as AM or FM radio transmissions).

In some examples, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some examples, a first communication chip 2012 may be dedicated to wireless communications, and a second communication chip 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display 2006 (or corresponding interface circuitry, as discussed above). The display 2006 may include any visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any device that generates an audible indicator, such as speakers, headsets, or earbuds.

The electrical device 2000 may include an audio input device 2018 (or corresponding interface circuitry, as discussed above). The audio input device 2018 may include any device that generates a signal representative of a sound, such as microphones, microphone arrays, or digital instruments (e.g., instruments having a musical instrument digital interface (MIDI) output).

The electrical device 2000 may include GPS circuitry 2016. The GPS circuitry 2016 may be in communication with a satellite-based system and may receive a location of the electrical device 2000, as known in the art.

The electrical device 2000 may include any other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include any other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the formation of deep trench capacitors within substrate cores containing a stack of multiple disaggregated glass cores with different CTEs. The deep trench capacitors of the example substrate cores disclosed herein provide enhanced power delivery, energy storage, signal coupling, and filtering for such substrate cores. The different CTEs define a CTE gradient that reduces stress within package substrates and, specifically, mitigates against seware failures that are known to arise in substrate with a single, solid glass core with a single CTE. As a result, examples disclosed herein improve yield loss in the fabrication of package substrates and also improve the reliability and/or useful life of IC packages relative to known techniques.

Systems, apparatus, articles of manufacture, and methods for stacks of glass layers including deep trench capacitors are disclosed. Further examples and combinations thereof include the following:

Example 1 includes a substrate comprising a first glass layer, a second glass layer coupled to the first glass layer, and a capacitor embedded in the first glass layer.

Example 2 includes the substrate of example 1, wherein the first glass core has a first coefficient of thermal expansion and the second glass core has a second coefficient of thermal expansion different than the first coefficient of thermal expansion.

Example 3 includes the substrate of example 1, further including an adhesive layer between the first glass layer and the second glass layer.

Example 4 includes the substrate of example 1, further including a buffer layer between the first glass layer and the second glass layer.

Example 5 includes the substrate of example 1, wherein the capacitor is a deep trench capacitor.

Example 6 includes the substrate of example 5, wherein the deep trench capacitor is a first deep trench capacitor and further including a second deep trench capacitor embedded in the second glass layer, the first deep trench capacitor is electrically coupled to the second deep trench capacitor.

Example 7 includes the substrate of example 1, further including a third glass layer, the second glass layer between the first glass layer and the third glass layer, a first layer between the second glass layer and the first glass layer, and a second layer between the third glass layer and the second glass layer.

Example 8 includes the substrate of example 7, wherein the first layer is a buffer layer and the second layer is an adhesive layer.

Example 9 includes the substrate of example 8, further including a second deep trench capacitor in the third glass layer.

Example 10 includes the substrate of example 7, wherein the first glass layer, the second glass layer, and the third glass layer have a same shape and thickness.

Example 11 includes an integrated circuit package including a first build-up region, a second build-up region, and a core between the first and second build-up regions, the core including a stack of glass layers, and a capacitor.

Example 12 includes the integrated circuit package of example 11, wherein the glass layers includes a first glass layer having a first coefficient of thermal expansion, and a second glass layer having a second coefficient of thermal expansion different than the first coefficient of thermal expansion.

Example 13 includes the integrated circuit package of example 12, wherein the glass layers further include a third glass layer, the second glass layer between the first glass layer and the third glass layer, the third glass layer having the first coefficient of thermal expansion.

Example 14 includes the integrated circuit package of example 11, wherein the capacitor is a deep trench capacitor.

Example 15 includes the integrated circuit package of example 14, wherein the deep trench capacitor is a first deep trench capacitor and the core further includes a second deep trench capacitor, the first deep trench capacitor is electrically coupled to the second deep trench capacitor.

Example 16 includes the integrated circuit package of example 11, wherein the stack includes a first quantity of glass layers and the core further includes a second quantity of deep trench capacitors including the deep trench capacitor, the second quantity equal to or greater than the first quantity.

Example 17 includes the integrated circuit package of example 11, wherein the core further includes an adhesive layer between a first one of the glass layers and a second one of the glass layers, and a buffer layer between the second one of the glass layers and a third one of the glass layers.

Example 18 includes an apparatus comprising a semiconductor die, a package substrate on the semiconductor die, the package substrate including a plurality of vertically arranged of glass layers, and a capacitor encompassed in a glass layer of the stack of glass layers.

Example 19 includes the apparatus of example 18, wherein the capacitor is a first deep trench capacitor and the apparatus further includes a second deep trench capacitor coupled to the first deep trench capacitor.

Example 20 includes the apparatus of example 19, wherein the first deep trench capacitor is aligned with the second deep trench capacitor in a direction perpendicular to the glass layers in the stack.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A substrate comprising:
a first glass layer;
a second glass layer coupled to the first glass layer; and
a capacitor embedded in the first glass layer.

2. The substrate of claim 1, wherein the first glass layer has a first coefficient of thermal expansion and the second glass layer has a second coefficient of thermal expansion different than the first coefficient of thermal expansion.

3. The substrate of claim 1, further including an adhesive layer between the first glass layer and the second glass layer.

4. The substrate of claim 1, further including a buffer layer between the first glass layer and the second glass layer.

5. The substrate of claim 1, wherein the capacitor is a deep trench capacitor.

6. The substrate of claim 5, wherein the deep trench capacitor is a first deep trench capacitor and further including a second deep trench capacitor embedded in the second glass layer, the first deep trench capacitor is electrically coupled to the second deep trench capacitor.

7. The substrate of claim 1, further including:
a third glass layer, the second glass layer between the first glass layer and the third glass layer;
a first layer between the second glass layer and the first glass layer; and
a second layer between the third glass layer and the second glass layer.

8. The substrate of claim 7, wherein the first layer is a buffer layer and the second layer is an adhesive layer.

9. The substrate of claim 8, further including a second deep trench capacitor in the third glass layer.

10. The substrate of claim 7, wherein the first glass layer, the second glass layer, and the third glass layer have a same shape and thickness.

11. An integrated circuit package including:
a first build-up region;
a second build-up region; and
a core between the first and second build-up regions, the core including:
a stack of glass layers; and
a capacitor.

12. The integrated circuit package of claim 11, wherein the glass layers includes:
a first glass layer having a first coefficient of thermal expansion; and
a second glass layer having a second coefficient of thermal expansion different than the first coefficient of thermal expansion.

13. The integrated circuit package of claim 12, wherein the glass layers further include a third glass layer, the second glass layer between the first glass layer and the third glass layer, the third glass layer having the first coefficient of thermal expansion.

14. The integrated circuit package of claim 11, wherein the capacitor is a deep trench capacitor.

15. The integrated circuit package of claim 14, wherein the deep trench capacitor is a first deep trench capacitor and the core further includes a second deep trench capacitor, the first deep trench capacitor is electrically coupled to the second deep trench capacitor.

16. The integrated circuit package of claim 11, wherein the stack includes a first quantity of the glass layers and the core further includes a second quantity of deep trench capacitors including the deep trench capacitor, the second quantity equal to or greater than the first quantity.

17. The integrated circuit package of claim 11, wherein the core further includes:
an adhesive layer between a first one of the glass layers and a second one of the glass layers; and
a buffer layer between the second one of the glass layers and a third one of the glass layers.

18. An apparatus comprising:
a semiconductor die;
a package substrate on the semiconductor die, the package substrate including a plurality of vertically arranged glass layers; and
a capacitor encompassed in a glass layer of the vertically arranged glass layers.

19. The apparatus of claim 18, wherein the capacitor is a first deep trench capacitor and the apparatus further includes a second deep trench capacitor coupled to the first deep trench capacitor.

20. The apparatus of claim 19, wherein the first deep trench capacitor is aligned with the second deep trench capacitor in a direction perpendicular to the vertically arranged glass layers.
